(19) United States
(12) Patent Application Publication
(10) Pub. No.: US 2007/0162795 A1
(43) Pub. Date: Jul. 12, 2007

(54) Test apparatus and test method

(75) Inventor: Takashi Hasegawa, Tokyo (JP)

Correspondence Address: OSHA LIANG L.L.P., 1221 MCKINNEY STREET, SUITE 2800, HOUSTON, TX, 77010, US

(73) Assignee: Advantest Corporation, Tokyo (JP)

(21) Appl. No.: 11/643,633

(22) Filed: Dec. 21, 2006

Related U.S. Application Data
(63) Continuation of application No. PCT/JP05/10231, filed on Jun. 3, 2005.

(30) Foreign Application Priority Data
Jun. 23, 2004 (JP) 2004-185585

(51) Int. Cl. G11C 29/00

(52) U.S. Cl. 714/718

(57) ABSTRACT

A test apparatus of the invention includes a pattern generator that generates an address signal and a test pattern signal to be supplied to a memory under test and an expectation signal to be output from the memory under test according to the address signal and the test pattern signal, a logic comparator that compares an output signal output from the memory under test and the expectation signal according to the address signal and the test pattern signal and outputs fail data when the output signal and the expectation signal is not identical with each other, and a plurality of fail counters that is provided corresponding to a plurality of area regions and respectively counts the number of the fail data for the output signal output from the memory under test corresponding to the address signal showing an address of a block included in an area region.

### CROSS REFERENCE TO RELATED APPLICATION

This is a continuation application of PCT/JP2005/010231 filed on Jun. 3, 2005, which claims priority from a Japanese Patent application No. 2004-185585 filed on Jun. 23, 2004, the contents of which are incorporated herein by reference.

### BACKGROUND

1. Field of the Invention

The present invention relates to a test apparatus and a test method. More particularly, the present invention relates to a test apparatus and a test method for testing a memory under test having a plurality of area regions respectively including a plurality of blocks.

2. Related Art

A conventional test apparatus tests each block of a memory under test having a plurality of blocks. Then, the test apparatus stores a test result for a block on a bad block memory in association with an address of the block and generates a map for bad blocks. Then, the test apparatus refers to the test result stored on the bad block memory to decide the good or bad of the memory under test. Specifically, the test apparatus counts the number of bad blocks stored on the bad block memory to decide the good or bad of the memory under test 150. Moreover, the number of bad blocks is not more than the number of repair blocks included in the memory under test, the test apparatus relieves the memory under test by means of replacing bad blocks by repair blocks.

Now, since a related patent document is not recognized, the description related to prior art documents is omitted.

FIG. 6 is a view showing a configuration of a flash memory according to a conventional art. In recent years, there has been developed a flash memory including repair blocks every area region included in a memory under test as shown in FIG. 6. Such a flash memory cannot relieve a certain area when the number of bad blocks is large than the number of repair blocks in this area region. However, the conventional test apparatus cannot detect the number of bad blocks and the location of area region when referring to a map for bad blocks generated on the bad block memory after terminating a test for all blocks in the memory under test. Therefore, although the number of bad blocks is large than the number of repair blocks in one area region in the middle of testing the memory under test, a testing time is idly increased and thus a throughput for a test is reduced because the test must be performed on all blocks.

### SUMMARY

Therefore, it is an advantage of the present invention to provide a test apparatus and a test method that can solve the foregoing problems. The above and other advantages can be achieved by combinations described in the independent claims. The dependent claims define further advantageous and exemplary combinations of the present invention.

According to the first aspect of the present invention, there is provided a test apparatus that tests a memory under test having a plurality of area regions respectively including a plurality of blocks. The test apparatus includes: a pattern generator that generates an address signal and a test pattern signal to be supplied to the memory under test and an expectation signal to be output from the memory under test according to the address signal and the test pattern signal; a logic comparator that compares an output signal output from the memory under test and the expectation signal according to the address signal and the test pattern signal and outputs fail data when the output signal and the expectation signal is not identical with each other; and a plurality of fail counters that is provided corresponding to the plurality of area regions and respectively counts the number of the fail data for the output signal output from the memory under test corresponding to the address signal showing an address of the block included in the area region.

The test apparatus may further include a bad block memory that stores the fail data output from the logic comparator in association with the address shown by the address signal, and the plurality of fail counters may count the number of the fail data when the logic comparator outputs the fail data and the fail data are not stored on the bad block memory in association with the address shown by the address signal.

The test apparatus may further include a counter control section that selects the fail counter provided corresponding to the area region including the block pointed by the address shown by the address signal based on the address signal generated from the pattern generator and supplies an enable signal to the selected fail counter.

The counter control section may include a plurality of counter enable generators that is provided corresponding to the plurality of fail counters and supplies the enable signal to the fail counter when the address signal showing the address of the block included in the area region corresponding to the fail counter has been supplied.

The counter enable generator may include: a minimum value setting register that holds a minimum value of the address of the block; a minimum value comparator that outputs an output value showing whether the address shown by the address signal generated from the pattern generator is not less than the minimum value held in the minimum value setting register; a maximum value setting register that holds a maximum value of the address of the block; a maximum value comparator that outputs an output value showing whether the address shown by the address signal generated from the pattern generator is not more than the maximum value held in the maximum value setting register; and an AND circuit that supplies the enable signal to the fail counter when the address shown by the address signal generated from the pattern generator is not less than the minimum value held in the minimum value setting register and is not more than the maximum value held in the maximum value setting register based on the output values from the minimum value comparator and the maximum value comparator.

The test apparatus may further include a limiter that stops a test for this area region when the number of fail data counted by the fail counter becomes larger than the number of repair blocks included in each area region in the memory under test.

The counter control section may include a counter enable memory that holds information identifying the fail counter that should supply the enable signal in association with the address of the block and supplies the enable signal to the fail counter held in association with the address shown by the address signal generated from the pattern generator.

The counter control section may include: an address selector that selects and outputs only a part of bit stream in the address shown by the address signal generated from the pattern generator; and a counter enable memory that holds information identifying the fail counter that should supply the enable signal in association with only a part of bit stream in the address of the block and supplies the enable signal to the fail counter held in association with the part of bit stream output from the address selector.

According to the second aspect of the present invention, there is provided a test method for testing a memory under test having a plurality of area regions respectively including a plurality of blocks. The test method includes: generating an address signal and a test pattern signal to be supplied to the memory under test and an expectation signal to be output from the memory under test according to the address signal and the test pattern signal; comparing an output signal output from the memory under test and the expectation signal according to the address signal and the test pattern signal and outputs fail data when the output signal and the expectation signal is not identical with each other; and counting the number of the fail data for the output signal output from the memory under test corresponding to the address signal showing an address of the block included in the area region for each of the plurality of area regions in parallel with the test for the memory under test.

The summary of the invention does not necessarily describe all necessary features of the present invention. The present invention may also be a sub-combination of the features described above.

### BRIEF DESCRIPTION OF THE DRAWINGS

FIG. 1 is a view exemplary showing a configuration of a test apparatus.

FIG. 2 is a view exemplary showing a configuration of a fail memory.

FIG. 3 is a view exemplary showing a configuration of a counter enable generator.

FIG. 4 is a view showing the first alternative example of the configuration of the fail memory.

FIG. 5 is a view showing the second alternative example of the configuration of the fail memory.

FIG. 6 is a view showing a configuration of a flash memory according to a conventional art.

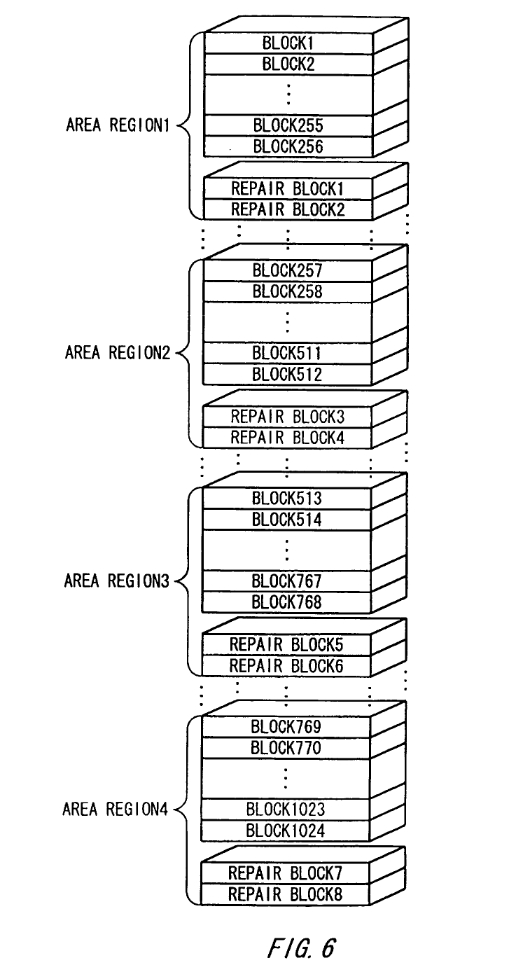

### DESCRIPTION OF EXEMPLARY EMBODIMENTS

The embodiments of the invention will now be described based on the preferred embodiments, which do not intend to limit the scope of the present invention, but just exemplify the invention. All of the features and the combinations thereof described in the embodiment are not necessarily essential to the invention.

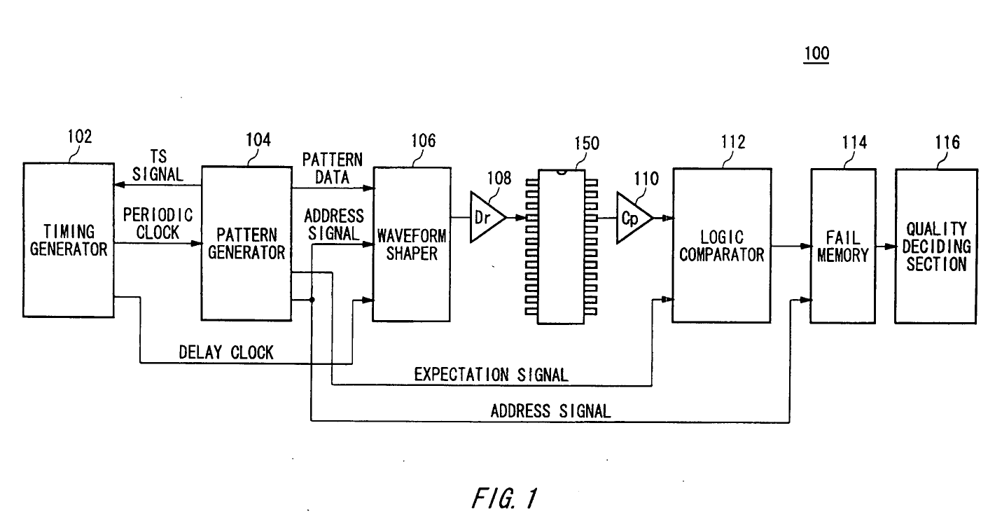

FIG. 1 is a view exemplary showing a configuration of a test apparatus 100 according to an embodiment of the present invention. The test apparatus 100 includes a timing generator 102, a pattern generator 104, a waveform shaper 106, a driver 108, a comparator 110, a logic comparator 112, a fail memory 114, and a quality deciding section 116.

In the test for the memory under test 150 having a plurality of area regions respectively including a plurality of blocks and a plurality of repair blocks, an object of the test apparatus 100 according to the present embodiment is to count the number of bad blocks every area region to accurately detect an area region capable of not being relieved and decide the good or bad of the memory under test 150 and further accurately perform assortment by performance of the memory under test 150.

The pattern generator 104 outputs a timing setting signal (hereinafter, referred to as “a TS signal”) to supply the signal to the timing generator 102. The timing generator 102 generates a cycle clock and a delay clock based on timing data designated by the TS signal in order to supply the cycle clock to the pattern generator 104 and supply the delay clock to the waveform shaper 106. Then, the pattern generator 104 generates an address signal and pattern data to be supplied to the memory under test 150 based on the cycle clock supplied from the timing generator 102, and supplies the signal and data to the waveform shaper 106. In addition, the address signal shows an address designating a block in the memory under test 150.

The waveform shaper 106 generates a test pattern signal shown by the pattern data generated from the pattern generator 104 based on the delay clock supplied from the timing generator 102. Then, the waveform shaper 106 supplies the address signal supplied from the pattern generator 104 and the generated test pattern signal to the memory under test 150 via the driver 108.

Moreover, the pattern generator 104 generates an expectation signal that is an output value of an output signal to be output from the memory under test 150 corresponding to the address signal and the test pattern signal, and supplies the expectation signal to the logic comparator 112. Then, the logic comparator 112 compares the output signal output from the memory under test 150 and the expectation signal according to the address signal and the test pattern signal, and outputs fail data when the output signal and the expectation signal are not identical with each other.

The fail memory 114 sequentially stores the fail data output from the logic comparator 112 in association with an address shown by the address signal generated from the pattern generator 104. Moreover, the fail memory 114 counts the number of fail data every area region included in the memory under test 150. Then, the quality deciding section 116 decides the good or bad for the memory under test 150 based on the fail data stored on the fail memory 114 and the number of fail data counted by the fail memory 114.

According to the test apparatus 100 of the present embodiment, since the test for area regions capable of not being relieved can be stopped by means of counting the number of bad blocks included in the memory under test 150 every area region in real time, it is possible to shorten a test for the memory under test 150.

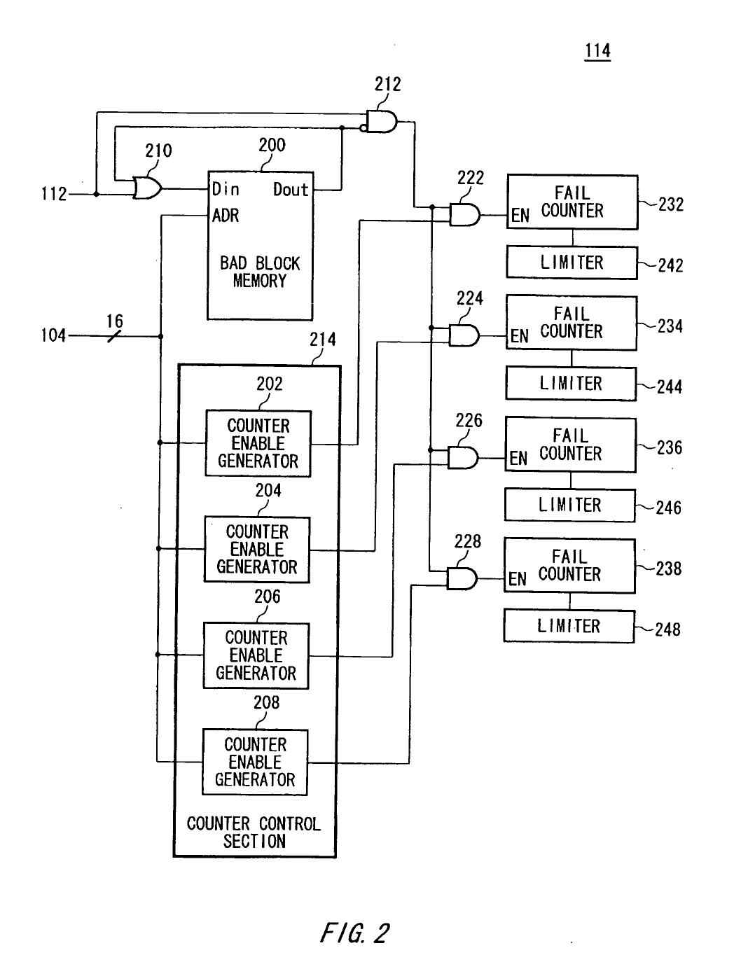

FIG. 2 is a view exemplary showing a configuration of the fail memory 114 according to the present embodiment. The fail memory 114 includes a bad block memory 200, an OR circuit 210, an AND circuit 212, a counter control section 214, AND circuits 222, 224, 226, and 228, fail counters 232, 234, 236, and 238, and limiters 242, 244, 246, and 248. The counter control section 214 has counter enable generators 202, 204, 206, and 208.

The bad block memory 200 stores the fail data output from the logic comparator 112 in association with the address shown by the address signal generated from the pattern generator 104. Specifically, the bad block memory 200 stores the fail data by a read modifying write operation. That is to say, the bad block memory 200 outputs data stored at the address shown by the address signal supplied from the pattern generator 104. Then, the OR circuit 210 performs an OR operation of the data output from the bad block memory 200 and the fail data supplied from the logic comparator 112, and supplies a result of the operation to the bad block memory 200. Then, the bad block memory 200 stores the data supplied from the OR circuit 210 at the address shown by the address signal supplied from the pattern generator 104. In this way, when the plurality of tests is performed on the same address in the memory under test 150, it is possible to generate a map for bad blocks.

The counter control section 214 selects the fail counter 232, 234, 236, or 238 provided corresponding to the plurality of area regions included in the memory under test 150 based on the address signal generated from the pattern generator 104, and supplies an enable signal to the selected fail counter. The plurality of counter enable generators 202, 204, 206, and 208 is respectively provided corresponding to the plurality of fail counters 232, 234, 236, and 238, and supplies the enable signal to each of the fail counters 232, 234, 236, and 238 when an address signal showing an address of a block included in an area region in the memory under test 150 corresponding to the fail counter has been supplied.

For example, assuming that the memory under test 150 has an area region having blocks of addresses #000-#0FF, an area region having blocks of addresses #100-#1FF, an area region having blocks of addresses #200-#2FF, an area region having blocks of addresses #300-#3FF, the counter enable generator 202 supplies the enable signal to the fail counter 232 when the address signal shows the addresses #000-#0FF, the counter enable generator 204 supplies the enable signal to the fail counter 234 when the address signal shows the addresses #100-#1FF, the counter enable generator 206 supplies the enable signal to the fail counter 236 when the address signal shows the addresses #200-#2FF, and the counter enable generator 208 supplies the enable signal to the fail counter 238 when the address signal shows the addresses #300-#3FF.

In addition, the fail memory 114 may further include an address selector that selects and outputs an address signal to be supplied to the bad block memory 200. Then, the bad block memory 200 may store fail data in association with an address shown by the address signal generated from the address selector. Moreover, the counter control section 214 may supply the enable signal to the fail counter 232, 234, 236, or 238 based on the address signal generated from the address selector.

The fail counters 232, 234, 236, and 238 are provided corresponding to the plurality of area regions included in the memory under test 150, and respectively count the number of fail data for an output signal output from the memory under test 150 corresponding to an address signal showing an address of a block included in an area region. The fail counters 232, 234, 236, and 238 count the number of fail data when the logic comparator 112 outputs fail data and fail data are not stored on the bad block memory 200 in association with the address shown by the address signal generated from the pattern generator 104.

Specifically, the AND circuit 212 performs an AND operation of the fail data “1” output from the logic comparator 112 and reversed data of data output from the bad block memory 200, which is stored at the address shown by the address signal generated from the pattern generator 104, and supplies a result of the operation to the AND circuits 222, 224, 226, and 228. Each of the AND circuits 222, 224, 226, and 228 performs an AND operation of the output from the AND circuit 212 and the enable signal “1” generated from each of the counter enable generators 202, 204, 206, and 208, and supplies a result of the operation to each of the fail counters 232, 234, 236, and 238. Then, each of the fail counters 232, 234, 236, and 238 increments a counted value when they have been respectively supplied with the enable signal “1” from the AND circuits 222, 224, 226, and 228.

When the number of fail data counted by either of the fail counters 232, 234, 236, and 238 becomes larger than the number of repair blocks included in the memory under test 150 every area region, the limiter 242, 244, 246, or 248 stops a test for this area region. Moreover, when the number of fail data counted by either of the fail counters 232, 234, 236, and 238 becomes larger than the number of repair blocks included in the memory under test 150 every area region, the limiter 242, 244, 246, or 248 may stop a test for the memory under test 150.

As described above, since the fail counters 232, 234, 236, and 238 are respectively provided for each area region included in the memory under test 150, it is possible to count the number of bad blocks every area region and thus appropriately decide the good or bad of the memory under test 150 having repair blocks every area region to relieve the memory under test. Moreover, since the number of bad blocks is counted in real time every area region in parallel with the test for the memory under test 150, it is possible to detect an area region capable of not being relieved and stop the test for this area region before terminating all tests for the memory under test 150. In this way, it is possible to shorten a testing time for the memory under test 150 and thus improve a throughput for the test.

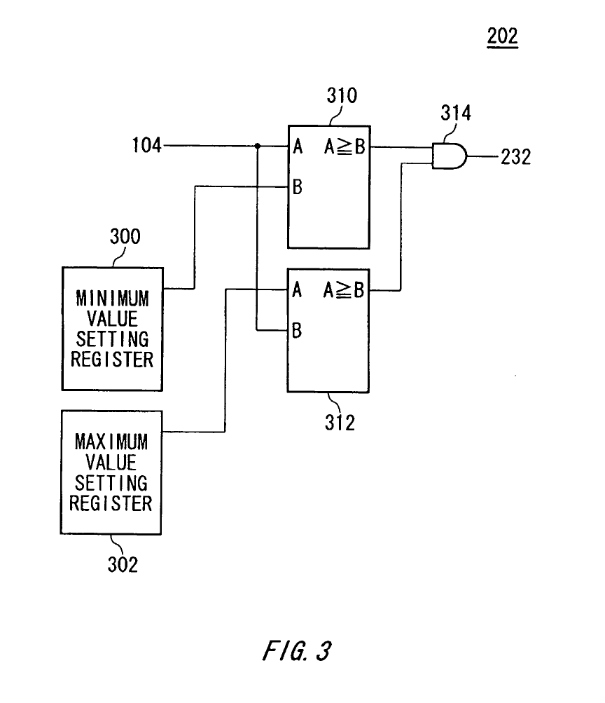

FIG. 3 is a view exemplary showing a configuration of the counter enable generator 202 according to the present embodiment. The counter enable generator 202 has a minimum value setting register 300, a maximum value setting register 302, a minimum value comparator 310, a maximum value comparator 312, and an AND circuit 314. In addition, since a configuration and a function of the counter enable generators 204, 206, and 208 are equal to those of the counter enable generator 202, the descriptions are omitted.

The minimum value setting register 300 holds a minimum value for an address of a block in a predetermined area region among the plurality of area regions included in the memory under test 150. The maximum value setting register 302 holds a maximum value for the address of the block in the predetermined area region. For example, when the address of the block in the predetermined area region is #000-#0FF, the minimum value setting register 300 holds #000 as a minimum value and the maximum value setting register 302 holds #0FF as a maximum value.

The minimum value comparator 310 compares the address shown by the address signal generated from the pattern generator 104 and the minimum value held in the minimum value setting register 300, and outputs an output value showing whether the address shown by the address signal is not less than the minimum value held in the minimum value setting register 300. For example, the minimum value comparator 310 outputs “1” when the address shown by the address signal is not less than the minimum value held in the minimum value setting register 300. The maximum value comparator 312 compares the address shown by the address signal generated from the pattern generator 104 and the maximum value held in the maximum value setting register 302, and outputs an output value showing whether the address shown by the address signal is not more than the maximum value held in the maximum value setting register 302. For example, the maximum value comparator 312 outputs “1” when the address shown by the address signal is not more than the maximum value held in the maximum value setting register 302.

The AND circuit 314 performs an AND operation of the output value from the minimum value comparator 310 and the output value from the maximum value comparator 312, and supplies a result of the operation to the fail counter 232. That is to say, the AND circuit 314 supplies the enable signal “1” to the fail counter 232 based on the output values from the minimum value comparator 310 and the maximum value comparator 312 when the address shown by the address signal generated from the pattern generator 104 is not less than the minimum value held in the minimum value setting register 300 and is not more than the maximum value held in the maximum value setting register 302.

By a configuration as described above, it is possible to count the number of bad blocks every area region in real time in parallel with the test for the memory under test 150. Therefore, it is possible to shorten a testing time for the memory under test 150 compared to a method for counting the number of bad blocks every area region with reference to the bad block memory 200 after terminating the test.

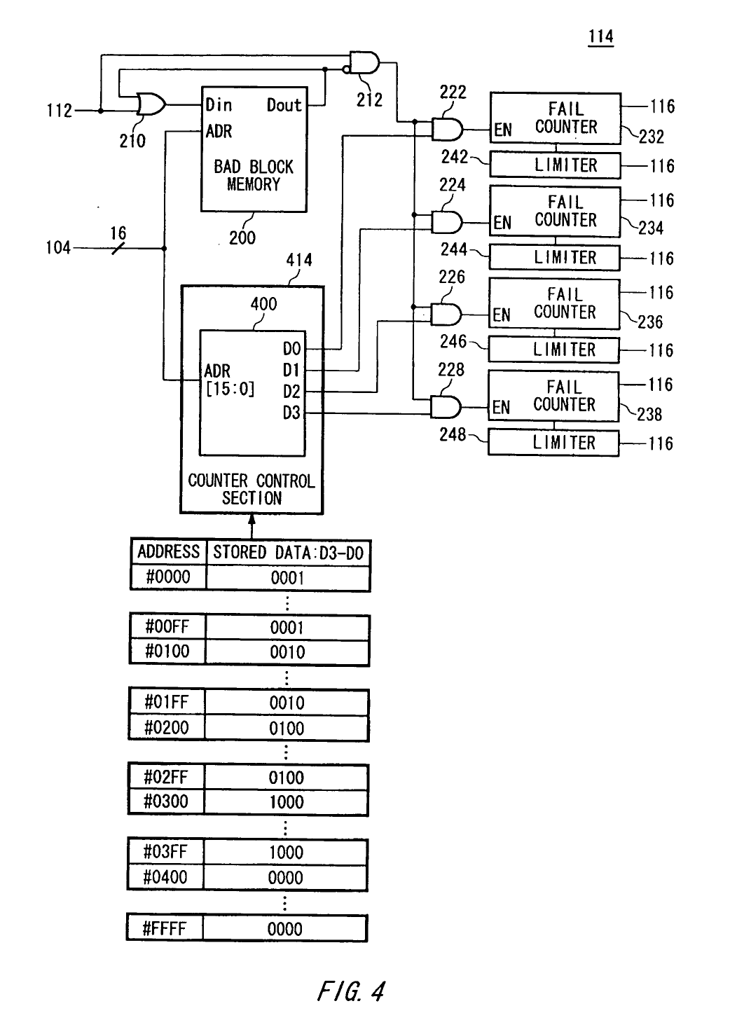

FIG. 4 is a view showing the first alternative example of the configuration of the fail memory 114 according to the present embodiment. The fail memory 114 of the present example has a counter control section 414 instead of the counter control section 214 included in the fail memory 114 shown in FIG. 2. Since the other configurational members included in the fail memory 114 of the present example are equal to those of the fail memory 114 shown in FIG. 2, the descriptions are omitted.

The counter control section 414 has a counter enable memory 400. The counter enable memory 400 holds information identifying the fail counter 232, 234, 236, or 238 to which the enable signal should be supplied in association with the address of the block included in the memory under test 150. Then, the counter enable memory 400 supplies the enable signal to the fail counter 232, 234, 236, or 238 held in association with the address shown by the address signal generated from the pattern generator 104.

Specifically, the counter enable memory 400 stores four-bit data corresponding to each of the fail counters 232, 234, 236, and 238 in association with the address of the block included in the memory under test 150. Then, the counter enable memory 400 respectively supplies each bit of four-bit data stored in association with the address shown by the address signal supplied from the pattern generator 104 to the fail counters 232, 234, 236, and 238. In the four-bit data, one bit corresponding to the fail counter to which the enable signal should be supplied is set to “1” and the other three bits are set to “0”.

According to the present example, since the counter control section 414 can be formed of only one counter enable memory 400, it is possible to simply realize a hardware configuration.

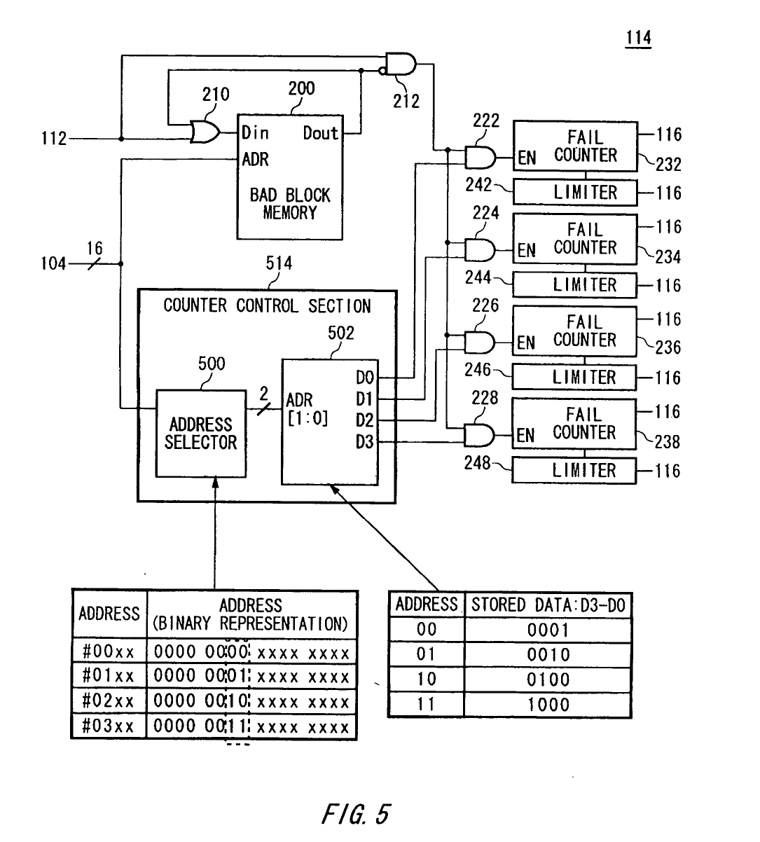

FIG. 5 is a view showing the second alternative example of the configuration of the fail memory 114 according to the present embodiment. The fail memory 114 of the present example has a counter control section 514 instead of the counter control section 214 included in the fail memory 114 shown in FIG. 2. Since the other configurational members included in the fail memory 114 of the present example are equal to those of the fail memory 114 shown in FIG. 2, the descriptions are omitted.

The counter control section 514 has an address selector 500 and a counter enable memory 502. The address selector 500 selects and outputs only a part of bit stream in the address shown by the address signal generated from the pattern generator 104. Then, the counter enable memory 502 holds information identifying the fail counter to which the enable signal should be supplied in association with a part of bit stream in the address of the block included in the memory under test 150. Then, the counter enable memory 502 supplies the enable signal to the fail counters 232, 234, 236, and 238 held in association with the part of bit stream output from the address selector 500.

Specifically, the address selector 500 selects and outputs a two-bit bit stream of the eighth bit and the ninth bit in a 16-bit address signal generated from the pattern generator 104. Then, the counter enable memory 502 stores four-bit data corresponding to each of the fail counters 232, 234, 236, and 238 in association with the two-bit bit stream. Then, the counter enable memory 502 respectively supplies each bit of four-bit data stored in association with the two-bit bit stream output from the address selector 500 to the fail counters 232, 234, 236, and 238. In the four-bit data, one bit corresponding to the fail counter to which the enable signal should be supplied is set to “1” and the other three bits are set to “0”.

In this manner, when the size of the plurality of area regions included in the memory under test 150 is equal to one another, the fail counter 232, 234, 236, or 238 to which the enable signal should be supplied can be selected with attention to only a part of bits capable of distinguish an area region among addresses of blocks included in the memory under test 150. According to the counter control section 514 of the present example, it is possible to reduce the size of the counter enable memory 502.

Although the present invention has been described by way of an exemplary embodiment, it should be understood that those skilled in the art might make many changes and substitutions without departing from the spirit and the scope of the present invention. It is obvious from the definition of the appended claims that embodiments with such modifications also belong to the scope of the present invention.

As apparent from the above descriptions, according to the test apparatus of the present invention, it is possible to shorten a testing time for the memory under test having repair blocks every area region.

What is claimed is:

1. A test apparatus that tests a memory under test having a plurality of area regions respectively including a plurality of blocks, the test apparatus comprising:
a pattern generator that generates an address signal and a test pattern signal to be supplied to the memory under test and an expectation signal to be output from the memory under test according to the address signal and the test pattern signal;
a logic comparator that compares an output signal output from the memory under test and the expectation signal according to the address signal and the test pattern signal and outputs fail data when the output signal and the expectation signal is not identical with each other; and
a plurality of fail counters that is provided corresponding to the plurality of area regions and respectively counts the number of the fail data for the output signal output from the memory under test corresponding to the address signal showing an address of the block included in the area region.

2. The test apparatus as claimed in claim 1, wherein
the test apparatus further comprises a bad block memory that stores the fail data output from the logic comparator in association with the address shown by the address signal, and
the plurality of fail counters counts the number of the fail data when the logic comparator outputs the fail data and the fail data are not stored on the bad block memory in association with the address shown by the address signal.

3. The test apparatus as claimed in claim 1, further comprising a counter control section that selects the fail counter provided corresponding to the area region including the block pointed by the address shown by the address signal based on the address signal generated from the pattern generator and supplies an enable signal to the selected fail counter.

4. The test apparatus as claimed in claim 3, wherein
the counter control section includes a plurality of counter enable generators that is provided corresponding to the plurality of fail counters and supplies the enable signal to the fail counter when the address signal showing the address of the block included in the area region corresponding to the fail counter has been supplied.

5. The test apparatus as claimed in claim 4, wherein
the counter enable generator includes:
a minimum value setting register that holds a minimum value of the address of the block;
a minimum value comparator that outputs an output value showing whether the address shown by the address signal generated from the pattern generator is not less than the minimum value held in the minimum value setting register;
a maximum value setting register that holds a maximum value of the address of the block;
a maximum value comparator that outputs an output value showing whether the address shown by the address signal generated from the pattern generator is not more than the maximum value held in the maximum value setting register; and
an AND circuit that supplies the enable signal to the fail counter when the address shown by the address signal generated from the pattern generator is not less than the minimum value held in the minimum value setting register and is not more than the maximum value held in the maximum value setting register based on the output values from the minimum value comparator and the maximum value comparator.

6. The test apparatus as claimed in claim 1, further comprising a limiter that stops a test for this area region when the number of fail data counted by the fail counter becomes larger than the number of repair blocks included in each area region in the memory under test.

7. The test apparatus as claimed in claim 3, wherein
the counter control section includes a counter enable memory that holds information identifying the fail counter that should supply the enable signal in association with the address of the block and supplies the enable signal to the fail counter held in association with the address shown by the address signal generated from the pattern generator.

8. The test apparatus as claimed in claim 3, wherein
the counter control section includes:
an address selector that selects and outputs only a part of bit stream in the address shown by the address signal generated from the pattern generator; and
a counter enable memory that holds information identifying the fail counter that should supply the enable signal in association with only a part of bit stream in the address of the block and supplies the enable signal to the fail counter held in association with the part of bit stream output from the address selector.

9. A test method for testing a memory under test having a plurality of area regions respectively including a plurality of blocks, the test method comprising:
generating an address signal and a test pattern signal to be supplied to the memory under test and an expectation signal to be output from the memory under test according to the address signal and the test pattern signal;
comparing an output signal output from the memory under test and the expectation signal according to the address signal and the test pattern signal and outputs fail data when the output signal and the expectation signal is not identical with each other; and
counting the number of the fail data for the output signal output from the memory under test corresponding to the address signal showing an address of the block included in the area region for each of the plurality of area regions in parallel with the test for the memory under test.
